(19) United States
(12) Patent Application Publication
(10) Pub. No.: US 2024/0297284 A1
(43) Pub. Date: Sep. 5, 2024

(54) SEMICONDUCTOR LIGHT-EMITTING DEVICE PACKAGE AND DISPLAY DEVICE

(71) Applicant: LG ELECTRONICS INC., Seoul (KR)

(72) Inventors: Daewoon HONG, Seoul (KR); Taehyun KIM, Seoul (KR); Dahye KIM, Seoul (KR); Sangtae PARK, Seoul (KR)

(73) Assignee: LG ELECTRONICS INC., Seoul (KR)

(21) Appl. No.: 18/270,801

(22) PCT Filed: Dec. 6, 2021
(86) PCT No.: PCT/KR2021/018323

§ 371 Date: Jul. 3, 2023

(30) Foreign Application Priority Data
Jan. 5, 2021 (KR) 10-2021-0000800

(51) Int. Cl. H01L 33/62; H01L 25/075; H01L 27/12; H01L 33/48; H01L 33/54

(52) U.S. Cl. CPC H01L 33/62; H01L 25/0753; H01L 27/124; H01L 33/486; H01L 33/54

(57) ABSTRACT

A light-emitting device package may comprise: a drive part which has a first pad and a second pad disposed at one surface thereof, the second pad being electrically connected to a light-emitting device, and controls driving of the light-emitting device; the light-emitting device disposed on the second pad; and a bonding part, wherein the light-emitting device and the bonding part may be disposed together on one surface of the drive part.

### TECHNICAL FIELD

Embodiments are applicable to the technical field of semiconductor light-emitting device packages and display devices, and relate to, for example, a semiconductor light-emitting device package and display device using a light emitting diode (LED) or micro LED.

### BACKGROUND ART

Recently, in a field of a display technology, display devices having excellent characteristics such as thinness, flexibility, and the like have been developed. On the other hand, currently commercialized major displays are represented by a liquid crystal display (LCD) and an organic light emitting diode (OLED).

A light emitting diode (LED), which is a well-known semiconductor light-emitting element that converts electric current into light, has been used as a light source for a display image of an electronic device including an information and communication device along with a GaP:N-based green LED, starting with commercialization of a red LED using a GaAsP compound semiconductor in 1962.

Recently, LEDs have become increasingly miniaturized, with micrometer-sized LEDs being fabricated and used as pixels in display devices. Compared to other display devices/panels, this micro-LED technology exhibits the characteristics of low power, high brightness, and high reliability, and is applicable even to flexible devices. Therefore, it has been actively researched by research institutes and companies in recent years.

As the size of LEDs becomes smaller, there are attempts to reduce the size of the light-emitting device package to reduce the size of the bezel.

However, in order to drive the LED, the semiconductor light-emitting device package requires a printed circuit board (PCB) on which the LED is mounted and a driverdriver to drive the LED. As a result, it has been difficult to reduce the size of the light-emitting device package beyond a certain level due to the structural arrangement of the IC chip, electrodes, and PCB board for driving the LED.

### DISCLOSURE

### Technical Problem

An object of the embodiments is to provide a light-emitting device package having a cross-sectional area reduced by the size of the cross-sectional area of a driverdriver and a display device including the light-emitting device package.

Another object of the embodiments is to provide a light-emitting device package in which the driverdriver and the light-emitting device are integrated and a display device including the light-emitting device package.

Another object of the embodiments is to provide a light-emitting device package which reduces manufacturing process costs and a display device including the light-emitting device package.

### Technical Solution

In one aspect of the present disclosure, a light-emitting device package may include a light-emitting device, a driverdriver configured to control driving of the light-emitting device, the driverdriver including a first pad, and a second pad electrically connected to the light-emitting device. The first pad and the second pad may be disposed on one surface of the driverdriver, and the light-emitting device may be disposed on the second pad.

The light-emitting device package may further include a bonding portion disposed on the first pad and electrically connected to the driverdriver.

Also, in a direction facing away from the driverdriver, a height of the bonding portion may be equal to a height of the light-emitting device or greater than the height of the light-emitting device.

When viewed from above, a cross-sectional area of the light-emitting device package may be equal to a cross-sectional area of the driverdriver.

The light-emitting device package may further include a protective member disposed on the driverdriver to cover the light-emitting device.

The driverdriver may include a peripheral portion and a central portion. The first pad may be disposed on the peripheral portion, and the second pad may be disposed on the central portion. The peripheral portion and the central portion may be arranged to have a step therebetween.

In another aspect of the present disclosure, a display device may include a circuit board comprising an electrode pad, and one or more light-emitting device packages disposed on one surface of the circuit board, and electrically connected to the circuit board. Each of the one or more light-emitting device packages may include a light-emitting device, and a driverdriver configured to control driving of the light-emitting device, the driverdriver including a first pad electrically connected to the electrode pad, and a second pad electrically connected to the light-emitting device. The first pad and the second pad may be disposed on one surface of the driver.

The display device may further include a bonding portion disposed on the first pad to electrically connect the circuit board and the driver.

The circuit board may be a transparent circuit board allowing light from the light-emitting device to be transmitted therethrough.

The circuit board may be an opaque circuit board comprising a passage allowing light from the light-emitting device to pass therethrough.

The circuit board may include metallic wiring formed on only one surface thereof facing the light-emitting device packages.

When viewed from above, each of the one or more light-emitting device packages may have the same cross-sectional area as the driver.

The display device may further include a protective member disposed on the driver to cover the light-emitting device packages.

The driver may further include a glass substrate arranged to face away from the one or more light-emitting device packages, the glass substrate being formed on an opposite surface of the circuit board.

In another aspect of the present disclosure, a display device may include a circuit board comprising an electrode pad, a driver arranged to face one surface of the circuit board and spaced apart from the circuit board by a specific distance, the driver may include a first pad for connection with the circuit board, and a second pad for connection of the light-emitting device, a light-emitting device bonded to the second pad of the driver by an electrode portion, and a bonding portion connected to the first pad of the driver and the electrode pad of the circuit board.

The circuit board may be a transparent circuit board allowing light from the light-emitting device to be transmitted therethrough

The circuit board may be an opaque circuit board comprising a passage allowing light from the light-emitting device to pass therethrough.

The circuit board may include metallic wiring formed on only one surface thereof facing the light-emitting device.

The display device may further include a protective member disposed to cover the light-emitting device and the driver.

The display device may further include a glass substrate arranged to face away from the driver, and formed in contact with an opposite surface of the circuit board.

In another aspect of the present disclosure, a display device may include a light-emitting device, a circuit board comprising an electrode pad on one surface thereof, a bonding portion connected to the electrode pad, a driver may include a first pad electrically connected to the bonding portion and a second pad electrically connected to the light-emitting device, a light-emitting device formed on the second pad and electrically connected to the second pad, and a glass substrate formed on an opposite surface of the circuit board to contact the circuit board. The first pad and the second pad may be formed on the same surface of the driver.

The display device may further include a protective member arranged to surround at least a portion of the circuit board, the bonding portion, the driver, and the light-emitting device.

### Advantageous Effects

With the semiconductor light-emitting device package and display device according to the embodiments, the size of the cross-sectional area of the light-emitting device package may be reduced by the size of the cross-sectional area of the driver.

With the semiconductor light-emitting device package and display device according to the embodiments, a light-emitting device package in which the driver and the light emitter are integrated may be implemented.

With the semiconductor light-emitting device package and display device according to the embodiments, a small curvature and transparent display may be implemented.

With the semiconductor light-emitting device package and display device according to embodiments, the light source may be easily repaired.

With the semiconductor light-emitting device package and display device according to embodiments, manufacturing process costs may be reduced by simplifying the package structure.

Furthermore, according to embodiments, there are additional technical effects not mentioned herein, which will be understood by one of ordinary skill in the art from the specification and drawings taken as a whole.

### DESCRIPTION OF DRAWINGS

FIG. 1 is a conceptual diagram illustrating an embodiment of a display device using a semiconductor light-emitting device according to the present disclosure;

FIG. 2 is a partially enlarged view showing a part A shown in FIG. 1;

FIGS. 3A and 3B are cross-sectional views taken along the cutting lines B-B and C-C in FIG. 2;

FIG. 4 is a conceptual diagram illustrating the flip-chip type semiconductor light-emitting device of FIG. 3;

FIGS. 5A to 5C are conceptual diagrams illustrating various examples of color implementation with respect to a flip-chip type semiconductor light-emitting device;

FIG. 6 shows cross-sectional views for a method of fabricating a display device using a semiconductor light-emitting device according to the present disclosure;

FIG. 7 is a perspective view of a display device using a semiconductor light-emitting device according to another embodiment of the present disclosure;

FIG. 8 is a cross-sectional view taken along a cutting line D-D shown in FIG. 8;

FIG. 9 is a conceptual diagram showing a vertical type semiconductor light-emitting device shown in FIG. 8;

FIG. 10 is a schematic cross-sectional view of a semiconductor light-emitting device package according to one embodiment;

FIG. 11 is a schematic cross-sectional view of a semiconductor light-emitting device package according to another embodiment;

FIG. 12 is a schematic top view of a semiconductor light-emitting device package according to another embodiment;

FIG. 13 is a schematic cross-sectional view of a semiconductor light-emitting device package according to another embodiment;

FIG. 14 is a schematic cross-sectional view of a semiconductor light-emitting device package according to another embodiment;

FIG. 15 is a schematic cross-sectional view of a display device according to another embodiment;

FIG. 16 is a schematic cross-sectional view of a display device according to another embodiment;

FIG. 17 is a schematic cross-sectional view of a display device according to another embodiment; and

FIG. 18 is a schematic cross-sectional view of a display device according to another embodiment.

### BEST MODE

Reference will now be made in detail to embodiments of the present disclosure, examples of which are illustrated in the accompanying drawings. Wherever possible, the same reference numbers will be used throughout the drawings to refer to the same or like parts, and redundant description thereof will be omitted. In describing embodiments disclosed in this specification, relevant well-known technologies may not be described in detail in order not to obscure the subject matter of the embodiments disclosed in this specification. In addition, it should be noted that the accompanying drawings are only for easy understanding of the embodiments disclosed in the present specification, and should not be construed as limiting the technical spirit disclosed in the present specification.

In addition, when an element such as a layer, region or module is described as being “on” another element, it is to be understood that the element may be directly on the other element or there may be an intermediate element between them.

Terms such as first and second may be used to describe various elements of the embodiments. However, various components according to the embodiments should not be limited by the above terms. These terms are only used to distinguish one element from another. For example, a first user input signal may be referred to as a second user input signal. Similarly, the second user input signal may be referred to as a first user input signal. Use of these terms should be construed as not departing from the scope of the various embodiments. The first user input signal and the second user input signal are both user input signals, but do not mean the same user input signals unless context clearly dictates otherwise.

The terms used to describe the embodiments are used for the purpose of describing specific embodiments, and are not intended to limit the embodiments. As used in the description of the embodiments and in the claims, the singular forms “a”, “an”, and “the” include plural referents unless the context clearly dictates otherwise. The expression “and/or” is used to include all possible combinations of terms. The terms such as “includes” or “has” are intended to indicate existence of figures, numbers, steps, elements, and/or components and should be understood as not precluding possibility of existence of additional existence of figures, numbers, steps, elements, and/or components. As used herein, conditional expressions such as “if” and “when” are not limited to an optional case and are intended to be interpreted, when a specific condition is satisfied, to perform the related operation or interpret the related definition according to the specific condition.

Furthermore, although the drawings are separately described for simplicity, embodiments implemented by combining at least two or more drawings are also within the scope of the present disclosure.

In addition, when an element such as a layer, region or module is described as being “on” another element, it is to be understood that the element may be directly on the other element or there may be an intermediate element between them.

The display device described herein is a concept including all display devices that display information with a unit pixel or a set of unit pixels. Therefore, the display device may be applied not only to finished products but also to parts. For example, a panel corresponding to a part of a digital TV also independently corresponds to the display device in the present specification. The finished products include a mobile phone, a smartphone, a laptop, a digital broadcasting terminal, a personal digital assistant (PDA), a portable multimedia player (PMP), a navigation system, a slate PC, a tablet, an Ultrabook, a digital TV, a desktop computer, and the like.

However, it will be readily apparent to those skilled in the art that the configuration according to the embodiments described herein is applicable even to a new product that will be developed later as a display device.

In addition, the semiconductor light-emitting device mentioned in this specification is a concept including an LED, a micro LED, and the like.

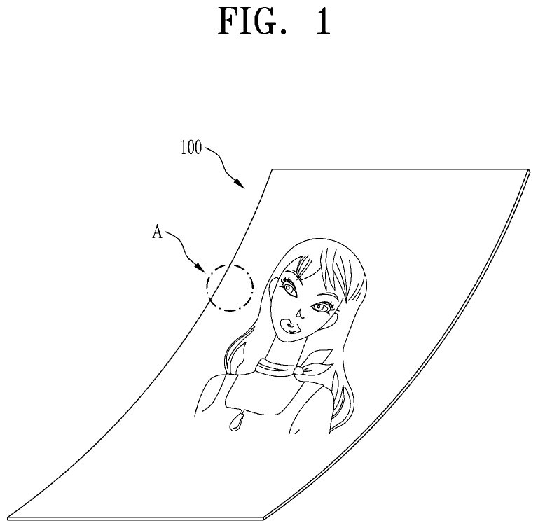

FIG. 1 is a conceptual view illustrating an embodiment of a display device using a semiconductor light-emitting device according to the present disclosure.

As shown in FIG. 1, information processed by a controller (not shown) of a display device 100 may be displayed using a flexible display.

The flexible display may include, for example, a display that can be warped, bent, twisted, folded, or rolled by external force.

Furthermore, the flexible display may be, for example, a display manufactured on a thin and flexible substrate that can be warped, bent, folded, or rolled like paper while maintaining the display characteristics of a conventional flat panel display.

When the flexible display remains in an unbent state (e.g., a state having an infinite radius of curvature) (hereinafter referred to as a first state), the display area of the flexible display forms a flat surface. When the display in the first state is changed to a bent state (e.g., a state having a finite radius of curvature) (hereinafter referred to as a second state) by external force, the display area may be a curved surface. As shown in FIG. 1, the information displayed in the second state may be visual information output on a curved surface. Such visual information may be implemented by independently controlling the light emission of sub-pixels arranged in a matrix form. The unit pixel may mean, for example, a minimum unit for implementing one color.

The unit pixel of the flexible display may be implemented by a semiconductor light-emitting device. In the present disclosure, a light emitting diode (LED) is exemplified as a type of the semiconductor light-emitting device configured to convert electric current into light. The LED may be formed in a small size, and may thus serve as a unit pixel even in the second state.

Hereinafter, a flexible display implemented using the LED will be described in more detail with reference to the drawings.

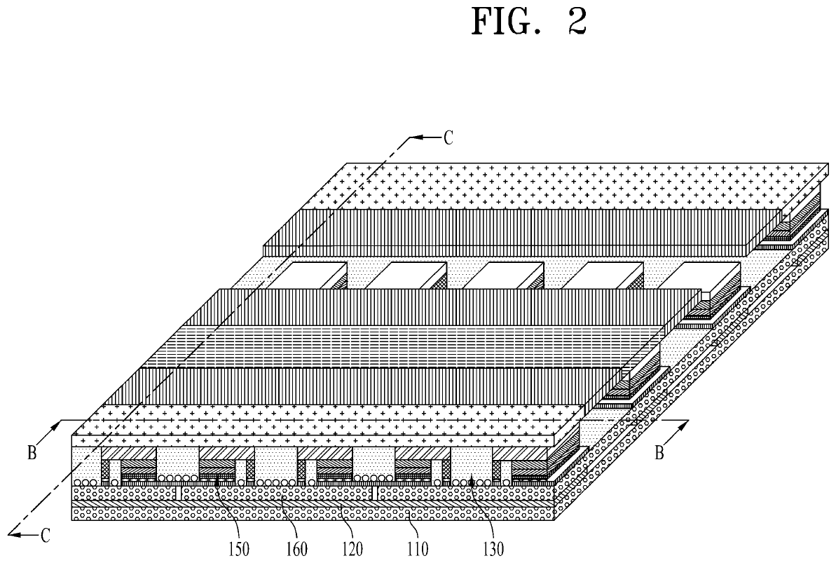

FIG. 2 is a partially enlarged view showing part A of FIG. 1.

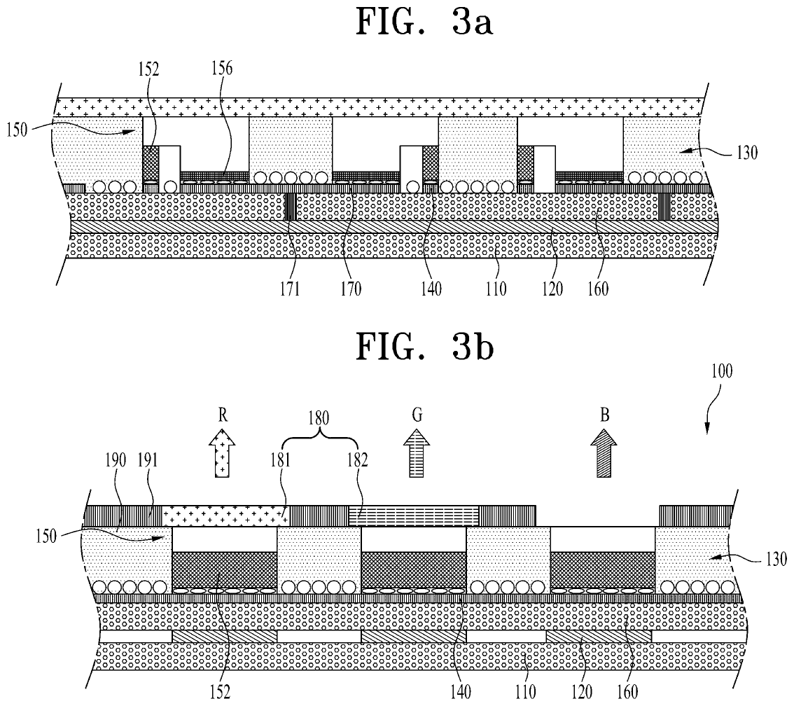

FIGS. 3A and 3B are cross-sectional views taken along lines B-B and C-C in FIG. 2.

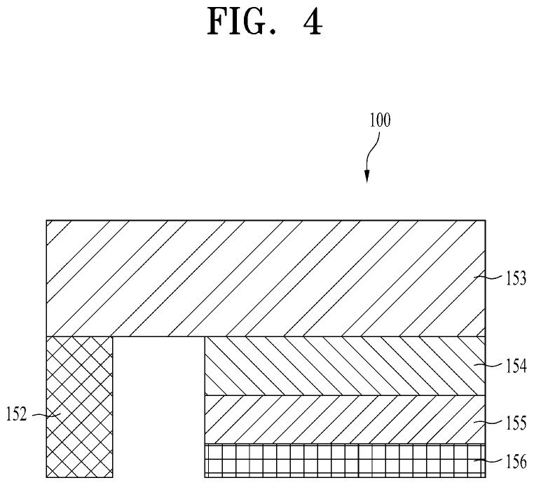

FIG. 4 is a conceptual view illustrating the flip-chip type semiconductor light-emitting device of FIG. 3.

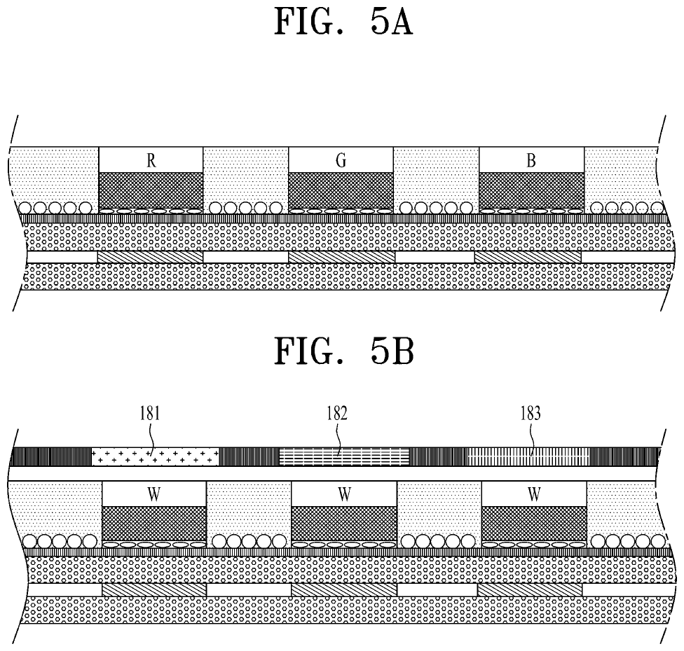

FIGS. 5A to 5C are conceptual views illustrating various examples of implementation of colors in relation to a flip-chip type semiconductor light-emitting device.

As shown in FIGS. 2, 3A and 3B, the display device 100 using a passive matrix (PM) type semiconductor light-emitting device is exemplified as the display device 100 using a semiconductor light-emitting device. However, the examples described below are also applicable to an active matrix (AM) type semiconductor light-emitting device.

The display device 100 shown in FIG. 1 may include a substrate 110, a first electrode 120, a conductive adhesive layer 130, a second electrode 140, and at least one semiconductor light-emitting device 150, as shown in FIG. 2.

The substrate 110 may be a flexible substrate. For example, to implement a flexible display device, the substrate 110 may include glass or polyimide (PI). Any insulative and flexible material such as polyethylene naphthalate (PEN) or polyethylene terephthalate (PET) may be employed. In addition, the substrate 110 may be formed of either a transparent material or an opaque material.

The substrate 110 may be a wiring substrate on which the first electrode 120 is disposed. Thus, the first electrode 120 may be positioned on the substrate 110.

As shown in FIG. 3A, an insulating layer 160 may be disposed on the substrate 110 on which the first electrode 120 is positioned, and an auxiliary electrode 170 may be positioned on the insulating layer 160. In this case, a stack in which the insulating layer 160 is laminated on the substrate 110 may be a single wiring substrate. More specifically, the insulating layer 160 may be formed of an insulative and flexible material such as PI, PET, or PEN, and may be integrated with the substrate 110 to form a single substrate.

The auxiliary electrode 170, which is an electrode that electrically connects the first electrode 120 and the semiconductor light-emitting device 150, is positioned on the insulating layer 160, and is disposed to correspond to the position of the first electrode 120. For example, the auxiliary electrode 170 may have a dot shape and may be electrically connected to the first electrode 120 by an electrode hole 171 formed through the insulating layer 160. The electrode hole 171 may be formed by filling a via hole with a conductive material.

As shown in FIG. 2 or 3A, a conductive adhesive layer 130 may be formed on one surface of the insulating layer 160, but embodiments of the present disclosure are not limited thereto. For example, a layer performing a specific function may be formed between the insulating layer 160 and the conductive adhesive layer 130, or the conductive adhesive layer 130 may be disposed on the substrate 110 without the insulating layer 160. In a structure in which the conductive adhesive layer 130 is disposed on the substrate 110, the conductive adhesive layer 130 may serve as an insulating layer.

The conductive adhesive layer 130 may be a layer having adhesiveness and conductivity. For this purpose, a material having conductivity and a material having adhesiveness may be mixed in the conductive adhesive layer 130. In addition, the conductive adhesive layer 130 may have ductility, thereby providing making the display device flexible.

As an example, the conductive adhesive layer 130 may be an anisotropic conductive film (ACF), an anisotropic conductive paste, a solution containing conductive particles, or the like. The conductive adhesive layer 130 may be configured as a layer that allows electrical interconnection in the direction of the Z-axis extending through the thickness, but is electrically insulative in the horizontal X-Y direction. Accordingly, the conductive adhesive layer 130 may be referred to as a Z-axis conductive layer (hereinafter, referred to simply as a “conductive adhesive layer”).

The ACF is a film in which an anisotropic conductive medium is mixed with an insulating base member. When the ACF is subjected to heat and pressure, only a specific portion thereof becomes conductive by the anisotropic conductive medium. Hereinafter, it will be described that heat and pressure are applied to the ACF. However, another method may be used to make the ACF partially conductive. The other method may be, for example, application of only one of the heat and pressure or UV curing.

In addition, the anisotropic conductive medium may be, for example, conductive balls or conductive particles. For example, the ACF may be a film in which conductive balls are mixed with an insulating base member. Thus, when heat and pressure are applied to the ACF, only a specific portion of the ACF is allowed to be conductive by the conductive balls. The ACF may contain a plurality of particles formed by coating the core of a conductive material with an insulating film made of a polymer material. In this case, as the insulating film is destroyed in a portion to which heat and pressure are applied, the portion is made to be conductive by the core. At this time, the cores may be deformed to form layers that contact each other in the thickness direction of the film. As a more specific example, heat and pressure are applied to the whole ACF, and an electrical connection in the Z-axis direction is partially formed by the height difference of a counterpart adhered by the ACF.

As another example, the ACF may contain a plurality of particles formed by coating an insulating core with a conductive material. In this case, as the conductive material is deformed (pressed) in a portion to which heat and pressure are applied, the portion is made to be conductive in the thickness direction of the film. As another example, the conductive material may be disposed through the insulating base member in the Z-axis direction to provide conductivity in the thickness direction of the film. In this case, the conductive material may have a pointed end.

The ACF may be a fixed array ACF in which conductive balls are inserted into one surface of the insulating base member. More specifically, the insulating base member may be formed of an adhesive material, and the conductive balls may be intensively disposed on the bottom portion of the insulating base member. Thus, when the base member is subjected to heat and pressure, it may be deformed together with the conductive balls, exhibiting conductivity in the vertical direction.

However, the present disclosure is not necessarily limited thereto, and the ACF may be formed by randomly mixing conductive balls in the insulating base member, or may be composed of a plurality of layers with conductive balls arranged on one of the layers (as a double-ACF).

The anisotropic conductive paste may be a combination of a paste and conductive balls, and may be a paste in which conductive balls are mixed with an insulating and adhesive base material. Also, the solution containing conductive particles may be a solution containing any conductive particles or nanoparticles.

Referring back to FIG. 3A, the second electrode 140 is positioned on the insulating layer 160 and spaced apart from the auxiliary electrode 170. That is, the conductive adhesive layer 130 is disposed on the insulating layer 160 having the auxiliary electrode 170 and the second electrode 140 positioned thereon.

After the conductive adhesive layer 130 is formed with the auxiliary electrode 170 and the second electrode 140 positioned on the insulating layer 160, the semiconductor light-emitting device 150 is connected thereto in a flip-chip form by applying heat and pressure. Thereby, the semiconductor light-emitting device 150 is electrically connected to the first electrode 120 and the second electrode 140.

Referring to FIG. 4, the semiconductor light-emitting device may be a flip chip-type light-emitting device.

For example, the semiconductor light-emitting device may include a p-type electrode 156, a p-type semiconductor layer 155 on which the p-type electrode 156 is formed, an active layer 154 formed on the p-type semiconductor layer 155, an n-type semiconductor layer 153 formed on the active layer 154, and an n-type electrode 152 disposed on the n-type semiconductor layer 153 and horizontally spaced apart from the p-type electrode 156. In this case, the p-type electrode 156 may be electrically connected to the auxiliary electrode 170, which is shown in FIG. 3, by the conductive adhesive layer 130, and the n-type electrode 152 may be electrically connected to the second electrode 140.

Referring back to FIGS. 2, 3A and 3B, the auxiliary electrode 170 may be elongated in one direction. Thus, one auxiliary electrode may be electrically connected to the plurality of semiconductor light-emitting devices 150. For example, p-type electrodes of semiconductor light-emitting devices on left and right sides of an auxiliary electrode may be electrically connected to one auxiliary electrode.

More specifically, the semiconductor light-emitting device 150 may be press-fitted into the conductive adhesive layer 130 by heat and pressure. Thereby, only the portions of the semiconductor light-emitting device 150 between the p-type electrode 156 and the auxiliary electrode 170 and between the n-type electrode 152 and the second electrode 140 may exhibit conductivity, and the other portions of the semiconductor light-emitting device 150 do not exhibit conductivity as they are not press-fitted. In this way, the conductive adhesive layer 130 interconnects and electrically connects the semiconductor light-emitting device 150 and the auxiliary electrode 170 and interconnects and electrically connects the semiconductor light-emitting device 150 and the second electrode 140.

The plurality of semiconductor light-emitting devices 150 may constitute a light-emitting device array, and a phosphor conversion layer 180 may be formed on the light-emitting device array.

The light-emitting device array may include a plurality of semiconductor light-emitting devices having different luminance values. Each semiconductor light-emitting device 150 may constitute a unit pixel and may be electrically connected to the first electrode 120. For example, a plurality of first electrodes 120 may be provided, and the semiconductor light-emitting devices may be arranged in, for example, several columns. The semiconductor light-emitting devices in each column may be electrically connected to any one of the plurality of first electrodes.

In addition, since the semiconductor light-emitting devices are connected in a flip-chip form, semiconductor light-emitting devices grown on a transparent dielectric substrate may be used. The semiconductor light-emitting devices may be, for example, nitride semiconductor light-emitting devices. Since the semiconductor light-emitting device 150 has excellent luminance, it may constitute an individual unit pixel even when it has a small size.

As shown in FIG. 3, a partition wall 190 may be formed between the semiconductor light-emitting devices 150. In this case, the partition wall 190 may serve to separate individual unit pixels from each other, and may be integrated with the conductive adhesive layer 130. For example, by inserting the semiconductor light-emitting device 150 into the ACF, the base member of the ACF may form the partition wall.

In addition, when the base member of the ACF is black, the partition wall 190 may have reflectance and increase contrast even without a separate black insulator.

As another example, a reflective partition wall may be separately provided as the partition wall 190. In this case, the partition wall 190 may include a black or white insulator depending on the purpose of the display device. When a partition wall including a white insulator is used, reflectivity may be increased. When a partition wall including a black insulator is used, it may have reflectance and increase contrast.

The phosphor conversion layer 180 may be positioned on the outer surface of the semiconductor light-emitting device 150. For example, the semiconductor light-emitting device 150 may be a blue semiconductor light-emitting device that emits blue (B) light, and the phosphor conversion layer 180 may function to convert the blue (B) light into a color of a unit pixel. The phosphor conversion layer 180 may be a red phosphor 181 or a green phosphor 182 constituting an individual pixel.

That is, the red phosphor 181 capable of converting blue light into red (R) light may be laminated on a blue semiconductor light-emitting device at a position of a unit pixel of red color, and the green phosphor 182 capable of converting blue light into green (G) light may be laminated on the blue semiconductor light-emitting device at a position of a unit pixel of green color. Only the blue semiconductor light-emitting device may be used alone in the portion constituting the unit pixel of blue color. In this case, unit pixels of red (R), green (G), and blue (B) may constitute one pixel. More specifically, a phosphor of one color may be laminated along each line of the first electrode 120. Accordingly, one line on the first electrode 120 may be an electrode for controlling one color. That is, red (R), green (G), and blue (B) may be sequentially disposed along the second electrode 140, thereby implementing a unit pixel.

However, embodiments of the present disclosure are not limited thereto. Unit pixels of red (R), green (G), and blue (B) may be implemented by combining the semiconductor light-emitting device 150 and the quantum dot (QD) rather than using the phosphor.

Also, a black matrix 191 may be disposed between the phosphor conversion layers to improve contrast. That is, the black matrix 191 may improve contrast of light and darkness.

However, embodiments of the present disclosure are not limited thereto, and anther structure may be applied to implement blue, red, and green colors.

Referring to FIG. 5A, each semiconductor light-emitting device may be implemented as a high-power light-emitting device emitting light of various colors including blue by using gallium nitride (GaN) as a main material and adding indium (In) and/or aluminum (Al).

In this case, each semiconductor light-emitting device may be a red, green, or blue semiconductor light-emitting device to form a unit pixel (sub-pixel). For example, red, green, and blue semiconductor light-emitting devices R, G, and B may be alternately disposed, and unit pixels of red, green, and blue may constitute one pixel by the red, green and blue semiconductor light-emitting devices. Thereby, a full-color display may be implemented.

Referring to FIG. 5B, the semiconductor light-emitting device 150a may include a white light-emitting device W having a yellow phosphor conversion layer, which is provided for each device. In this case, in order to form a unit pixel, a red phosphor conversion layer 181, a green phosphor conversion layer 182, and a blue phosphor conversion layer 183 may be disposed on the white light-emitting device W. In addition, a unit pixel may be formed using a color filter repeating red, green, and blue on the white light-emitting device W.

Referring to FIG. 5C, a red phosphor conversion layer 181, a green phosphor conversion layer 185, and a blue phosphor conversion layer 183 may be provided on a ultraviolet light-emitting device. Not only visible light but also ultraviolet (UV) light may be used in the entire region of the semiconductor light-emitting device. In an embodiment, UV may be used as an excitation source of the upper phosphor in the semiconductor light-emitting device.

Referring back to this example, the semiconductor light-emitting device is positioned on the conductive adhesive layer to constitute a unit pixel in the display device. Since the semiconductor light-emitting device has excellent luminance, individual unit pixels may be configured despite even when the semiconductor light-emitting device has a small size.

Regarding the size of such an individual semiconductor light-emitting device, the length of each side of the device may be, for example, 80 μm or less, and the device may have a rectangular or square shape. When the semiconductor light-emitting device has a rectangular shape, the size thereof may be less than or equal to 20 μm×80 μm.

In addition, even when a square semiconductor light-emitting device having a side length of 10 μm is used as a unit pixel, sufficient brightness to form a display device may be obtained.

Therefore, for example, in case of a rectangular pixel having a unit pixel size of 600 μm×300 μm (i.e., one side by the other side), a distance of a semiconductor light-emitting device becomes sufficiently long relatively.

Thus, in this case, it is able to implement a flexible display device having high image quality over HD image quality.

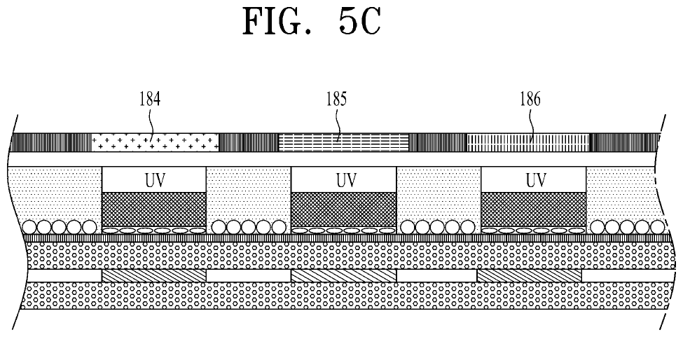

The above-described display device using the semiconductor light-emitting device may be prepared by a new fabricating method. Such a fabricating method will be described with reference to FIG. 6 as follows.

FIG. 6 shows cross-sectional views for a method of fabricating a display device using a semiconductor light-emitting device according to the present disclosure.

Referring to FIG. 6, first of all, a conductive adhesive layer 130 is formed on an insulating layer 160 located between an auxiliary electrode 170 and a second electrode 140. The insulating layer 160 is tacked on a wiring substrate 110. On the wiring substrate 110, a first electrode 120, the auxiliary electrode 170 and the second electrode 140 are disposed. In this case, the first electrode 120 and the second electrode 140 may be disposed in mutually orthogonal directions, respectively. In order to implement a flexible display device, the wiring substrate 110 and the insulating layer 160 may include glass or polyimide (PI) each.

For example, the conductive adhesive layer 130 may be implemented by an anisotropic conductive film. To this end, an anisotropic conductive film may be coated on the substrate on which the insulating layer 160 is located.

Subsequently, a temporary substrate 112, on which a plurality of semiconductor light-emitting devices 150 configuring individual pixels are located to correspond to locations of the auxiliary electrode 170 and the second electrodes 140, is disposed in a manner that the semiconductor light-emitting device 150 confronts the auxiliary electrode 170 and the second electrode 140.

In this regard, the temporary 112 substrate 112 is a growing substrate for growing the semiconductor light-emitting device 150 and may include a sapphire or silicon substrate.

The semiconductor light-emitting device is configured to have a space and size for configuring a display device when formed in unit of wafer, thereby being effectively used for the display device.

Subsequently, the wiring substrate 110 and the temporary substrate 112 are thermally compressed together. By the thermocompression, the wiring substrate 110 and the temporary substrate 112 are bonded together. Owing to the property of an anisotropic conductive film having conductivity by thermocompression, only a portion among the semiconductor light-emitting device 150, the auxiliary electrode 170 and the second electrode 140 has conductivity, via which the electrodes and the semiconductor light-emitting device 150 may be connected electrically. In this case, the semiconductor light-emitting device 150 is inserted into the anisotropic conductive film, by which a partition may be formed between the semiconductor light-emitting devices 150.

Then the temporary substrate 112 is removed. For example, the temporary substrate 112 may be removed using Laser Lift-Off (LLO) or Chemical Lift-Off (CLO).

Finally, by removing the temporary substrate 112, the semiconductor light-emitting devices 150 exposed externally. If necessary, the wiring substrate 110 to which the semiconductor light-emitting devices 150 are coupled may be coated with silicon oxide (SiOx) or the like to form a transparent insulating layer (not shown).

In addition, a step of forming a phosphor layer on one side of the semiconductor light-emitting device 150 may be further included. For example, the semiconductor light-emitting device 150 may include a blue semiconductor light-emitting device emitting Blue (B) light, and a red or green phosphor for converting the blue (B) light into a color of a unit pixel may form a layer on one side of the blue semiconductor light-emitting device.

The above-described fabricating method or structure of the display device using the semiconductor light-emitting device may be modified into various forms. For example, the above-described display device may employ a vertical semiconductor light-emitting device.

Furthermore, a modification or embodiment described in the following may use the same or similar reference numbers for the same or similar configurations of the former example and the former description may apply thereto.

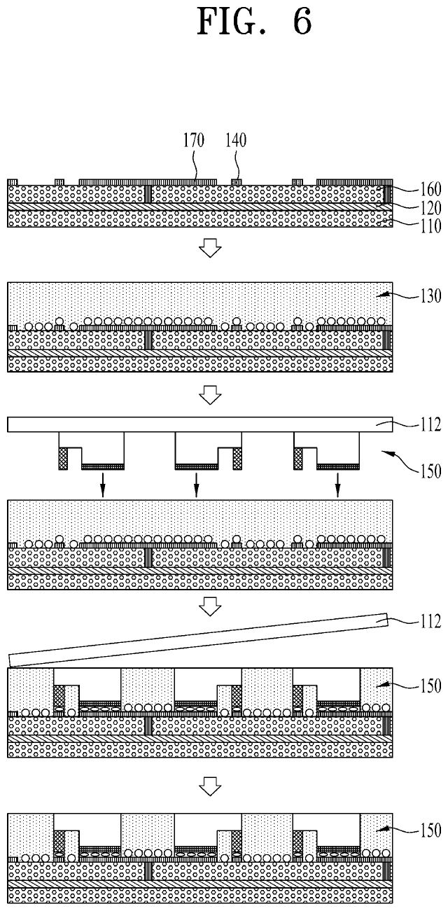

FIG. 7 is a perspective view of a display device using a semiconductor light-emitting device according to another embodiment of the present disclosure.

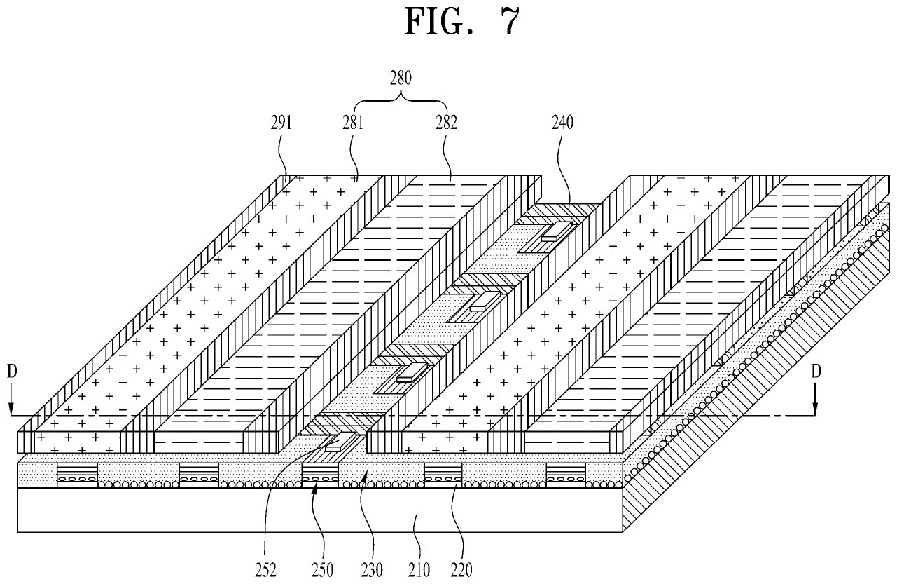

FIG. 8 is a cross-sectional view taken along a cutting line D-D shown in FIG. 8.

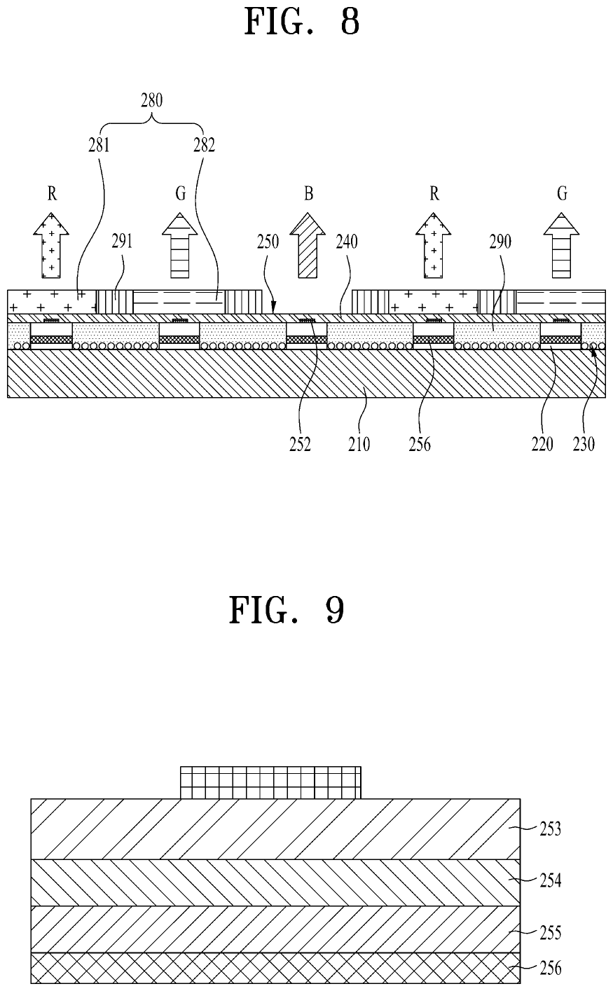

FIG. 9 is a conceptual diagram showing a vertical type semiconductor light-emitting device shown in FIG. 8.

Referring to the present drawings, a display device may employ a vertical semiconductor light-emitting device of a Passive Matrix (PM) type.

The display device includes a substrate 210, a first electrode 220, a conductive adhesive layer 230, a second electrode 240 and at least one semiconductor light-emitting device 250.

The substrate 210 is a wiring substrate on which the first electrode 220 is disposed and may contain polyimide (PI) to implement a flexible display device. Besides, the substrate 210 may use any substance that is insulating and flexible.

The first electrode 210 is located on the substrate 210 and may be formed as a bar type electrode that is long in one direction. The first electrode 220 may be configured to play a role as a data electrode.

The conductive adhesive layer 230 is formed on the substrate 210 where the first electrode 220 is located. Like a display device to which a light-emitting device of a flip chip type is applied, the conductive adhesive layer 230 may include one of an Anisotropic Conductive Film (ACF), an anisotropic conductive paste, a conductive particle contained solution and the like. Yet, in the present embodiment, a case of implementing the conductive adhesive layer 230 with the anisotropic conductive film is exemplified.

After the conductive adhesive layer has been placed in the state that the first electrode 220 is located on the substrate 210, if the semiconductor light-emitting device 250 is connected by applying heat and pressure thereto, the semiconductor light-emitting device 250 is electrically connected to the first electrode 220. In doing so, the semiconductor light-emitting device 250 is preferably disposed to be located on the first electrode 220.

If heat and pressure is applied to an anisotropic conductive film, as described above, since the anisotropic conductive film has conductivity partially in a thickness direction, the electrical connection is established. Therefore, the anisotropic conductive film is partitioned into a conductive portion and a non-conductive portion.

Furthermore, since the anisotropic conductive film contains an adhesive component, the conductive adhesive layer 230 implements mechanical coupling between the semiconductor light-emitting device 250 and the first electrode 220 as well as mechanical connection.

Thus, the semiconductor light-emitting device 250 is located on the conductive adhesive layer 230, via which an individual pixel is configured in the display device. As the semiconductor light-emitting device 250 has excellent luminance, an individual unit pixel may be configured in small size as well. Regarding a size of the individual semiconductor light-emitting device 250, a length of one side may be equal to or smaller than 80 μm for example and the individual semiconductor light-emitting device 250 may include a rectangular or square device. For example, the rectangular device may have a size equal to or smaller than 20 μm×80 μm.

The semiconductor light-emitting device 250 may have a vertical structure.

Among the vertical type semiconductor light-emitting devices, a plurality of second electrodes 240 respectively and electrically connected to the vertical type semiconductor light-emitting devices 250 are located in a manner of being disposed in a direction crossing with a length direction of the first electrode 220.

Referring to FIG. 9, the vertical type semiconductor light-emitting device 250 includes a p-type electrode 256, a p-type semiconductor layer 255 formed on the p-type electrode 256, an active layer 254 formed on the p-type semiconductor layer 255, an n-type semiconductor layer 253 formed on the active layer 254, and an n-type electrode 252 formed on then-type semiconductor layer 253. In this case, the p-type electrode 256 located on a bottom side may be electrically connected to the first electrode 220 by the conductive adhesive layer 230, and the n-type electrode 252 located on a top side may be electrically connected to a second electrode 240 described later. Since such a vertical type semiconductor light-emitting device 250 can dispose the electrodes at top and bottom, it is considerably advantageous in reducing a chip size.

Referring to FIG. 8 again, a phosphor layer 280 may formed on one side of the semiconductor light-emitting device 250. For example, the semiconductor light-emitting device 250 may include a blue semiconductor light-emitting device 251 emitting blue (B) light, and a phosphor layer 280 for converting the blue (B) light into a color of a unit pixel may be provided. In this regard, the phosphor layer 280 may include a red phosphor 281 and a green phosphor 282 configuring an individual pixel.

Namely, at a location of configuring a red unit pixel, the red phosphor 281 capable of converting blue light into red (R) light may be stacked on a blue semiconductor light-emitting device. At a location of configuring a green unit pixel, the green phosphor 282 capable of converting blue light into green (G) light may be stacked on the blue semiconductor light-emitting device. Moreover, the blue semiconductor light-emitting device may be singly usable for a portion that configures a blue unit pixel. In this case, the unit pixels of red (R), green (G) and blue (B) may configure a single pixel.

Yet, the present disclosure is non-limited by the above description. In a display device to which a light-emitting device of a flip chip type is applied, as described above, a different structure for implementing blue, red and green may be applicable.

Regarding the present embodiment again, the second electrode 240 is located between the semiconductor light-emitting devices 250 and connected to the semiconductor light-emitting devices electrically. For example, the semiconductor light-emitting devices 250 are disposed in a plurality of columns, and the second electrode 240 may be located between the columns of the semiconductor light-emitting devices 250.

Since a distance between the semiconductor light-emitting devices 250 configuring the individual pixel is sufficiently long, the second electrode 240 may be located between the semiconductor light-emitting devices 250.

The second electrode 240 may be formed as an electrode of a bar type that is long in one direction and disposed in a direction vertical to the first electrode.

In addition, the second electrode 240 and the semiconductor light-emitting device 250 may be electrically connected to each other by a connecting electrode protruding from the second electrode 240. Particularly, the connecting electrode may include a n-type electrode of the semiconductor light-emitting device 250. For example, the n-type electrode is formed as an ohmic electrode for ohmic contact, and the second electrode covers at least one portion of the ohmic electrode by printing or deposition. Thus, the second electrode 240 and the n-type electrode of the semiconductor light-emitting device 250 may be electrically connected to each other.

Referring to FIG. 8 again, the second electrode 240 may be located on the conductive adhesive layer 230. In some cases, a transparent insulating layer (not shown) containing silicon oxide (SiOx) and the like may be formed on the substrate 210 having the semiconductor light-emitting device 250 formed thereon. If the second electrode 240 is placed after the transparent insulating layer has been formed, the second electrode 240 is located on the transparent insulating layer. Alternatively, the second electrode 240 may be formed in a manner of being spaced apart from the conductive adhesive layer 230 or the transparent insulating layer.

If a transparent electrode of Indium Tin Oxide (ITO) or the like is sued to place the second electrode 240 on the semiconductor light-emitting device 250, there is a problem that ITO substance has poor adhesiveness to an n-type semiconductor layer. Therefore, according to the present disclosure, as the second electrode 240 is placed between the semiconductor light-emitting devices 250, it is advantageous in that a transparent electrode of ITO is not used. Thus, light extraction efficiency can be improved using a conductive substance having good adhesiveness to an n-type semiconductor layer as a horizontal electrode without restriction on transparent substance selection.

Referring to FIG. 8 again, a partition 290 may be located between the semiconductor light-emitting devices 250. Namely, in order to isolate the semiconductor light-emitting device 250 configuring the individual pixel, the partition 290 may be disposed between the vertical type semiconductor light-emitting devices 250. In this case, the partition 290 may play a role in separating the individual unit pixels from each other and be formed with the conductive adhesive layer 230 as an integral part. For example, by inserting the semiconductor light-emitting device 250 in an anisotropic conductive film, a base member of the anisotropic conductive film may form the partition.

In addition, if the base member of the anisotropic conductive film is black, the partition 290 may have reflective property as well as a contrast ratio may be increased, without a separate block insulator.

For another example, a reflective partition may be separately provided as the partition 190. The partition 290 may include a black or white insulator depending on the purpose of the display device.

In case that the second electrode 240 is located right onto the conductive adhesive layer 230 between the semiconductor light-emitting devices 250, the partition 290 may be located between the vertical type semiconductor light-emitting device 250 and the second electrode 240 each. Therefore, an individual unit pixel may be configured using the semiconductor light-emitting device 250. Since a distance between the semiconductor light-emitting devices 250 is sufficiently long, the second electrode 240 can be placed between the semiconductor light-emitting devices 250. And, it may bring an effect of implementing a flexible display device having HD image quality.

In addition, as shown in FIG. 8, a black matrix 291 may be disposed between the respective phosphors for the contrast ratio improvement. Namely, the black matrix 291 may improve the contrast between light and shade.

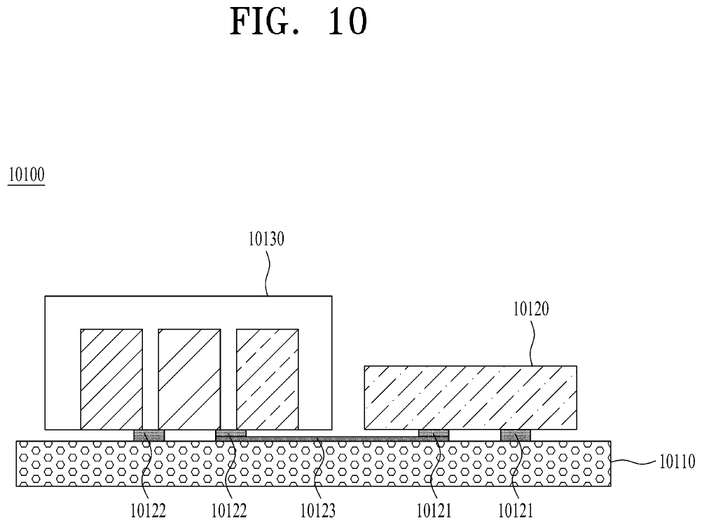

FIG. 10 is a schematic cross-sectional view of a semiconductor light-emitting device package according to one embodiment.

As shown in FIG. 10, a light-emitting device package 10100 according to one embodiment may include a wiring substrate 10110 (e.g., the substrate described with reference to FIGS. 2 to 3 and 5 to 8), a driver 10120, and a light-emitting device 10130 (e.g., the semiconductor light-emitting device described with reference to FIGS. 1 to 9).

In the light-emitting device package 10100 according to one embodiment, the driver 10120 may be disposed on the wiring substrate 10110, and the light-emitting device 10130 may be disposed on the wiring substrate 10110 in parallel with the driver 10120. The wiring substrate 10110 according to one embodiment may include a first pad 10121 electrically connected to the driver 10120, a second pad 10122 electrically connected to the light-emitting device 10130, and an electrical wiring 10123 electrically connecting the first pad 10121 and the second pad 10122. In other words, the light-emitting device 10130 and the driver 10120 may be electrically connected by the wiring substrate 10110.

The wiring substrate 10110 according to one embodiment may have an electrode pattern corresponding to the light-emitting device 10130. That is, the light-emitting device 10130 may be mounted and positioned on the wiring substrate 10110. The wiring substrate 10110 may be a substrate that includes printed circuitry to apply electrical signals to the light-emitting device 10130. Alternatively, although not shown in FIG. 10, a separate printed circuit board may be provided under the wiring substrate 10110. The driver 10120 according to embodiments may control the light-emitting device 10130. For example, it may control the on/off of the light-emitting device 10120.

The driver 10120 according to one embodiment may be, for example, a driver IC. While FIG. 10 illustrates an example in which one driver 10120 controls one light-emitting device 10130 in one light-emitting device package 10100, the number of drivers 10120 is not limited thereto. For example, the driver 10120 may be configured to control multiple light-emitting devices 10130 simultaneously or sequentially.

The light-emitting device package 10100 including the wiring substrate 10120 according to one embodiment may be formed using a wire bonding or flip process. However, the light-emitting device package 10100 including the wiring substrate 10120 according to one embodiment is required to secure an area of more than a certain size as the driver 10120 and the light-emitting device 10130 are disposed side by side. In other words, it is difficult to reduce the size of the light-emitting device package 10100 below a certain size, and therefore it is difficult to reduce the size of the bezel below a certain size. To address this issue, attempts have been made to form the light-emitting device package 10100 using a TSV (Through Silicon Via) technique. However, in this case, excessive costs are incurred during the TSV process.

Hereinafter, a method for reducing the size of the light-emitting device package without incurring excessive costs will be described in detail.

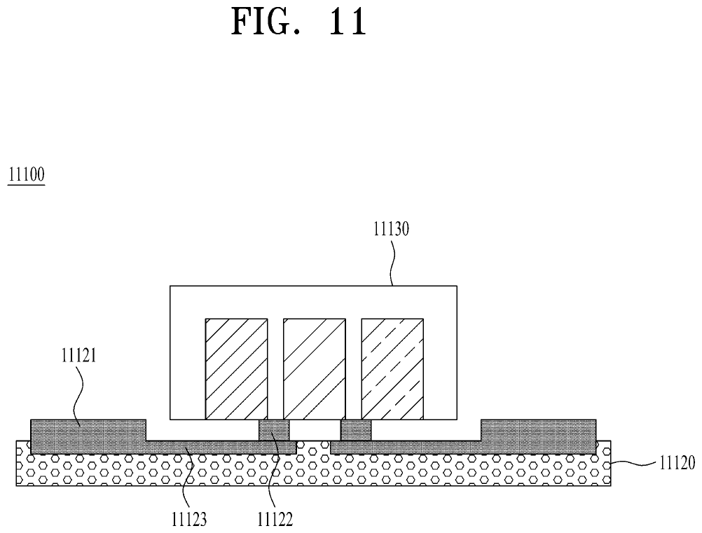

FIG. 11 is a schematic cross-sectional view of a semiconductor light-emitting device package according to another embodiment.

As shown in FIG. 11, according to another embodiment, the light-emitting device package 11100 may include a driver 11120 (e.g., the driver described with reference to FIG. 10) and a light-emitting device 11130 (e.g., the semiconductor light-emitting device described with reference to FIGS. 1 to 9 or the light-emitting device described with reference to FIG. 10). The light-emitting device 11130 according to this embodiments may be positioned on one surface of the driver 11120. Accordingly, according to this embodiment, the light-emitting device package 11100 may reduce the size of one pixel by disposing the light-emitting device 11130 (e.g., a semiconductor light-emitting device emitting R, G, and B) on the driver 11120. According to this embodiment, the light-emitting device package 11100 may include the driver 11120 and the light-emitting device 11130, which are arranged in a vertical direction. In other words, the light-emitting device package 11100 according to this embodiment may include the driver 11120 and the light-emitting device 11130 in an integrated manner.

Specifically, a first pad 11121 (e.g., the first pad described with reference to FIG. 10) and a second pad 11122 (e.g., the second pad described with reference to FIG. 10) may be disposed on one surface of the driver 11120. According to this embodiment, the first pad 11121 may be an electrode that electrically connects the external circuitry and the driver 11120 to each other. The second pad 11122 may be an electrode that electrically connects the driver 11120 and the light-emitting device 11130. According to this embodiment, the first pad 11121 and the second pad 11122 may be electrically connected to each other by an electrical wire 11123 (e.g., the electrical wire described with reference to FIG. 10) formed on one surface of the driver 11120. Thus, the first pad 11121, the second pad 11122, and the electrical wire 11123 may be located together on one surface of the driver 11120. In other words, nothing may be formed on the opposite surface of the driver 11120 where the first pad 11121, the second pad 11122, and the electrical wire 11123 are not positioned.

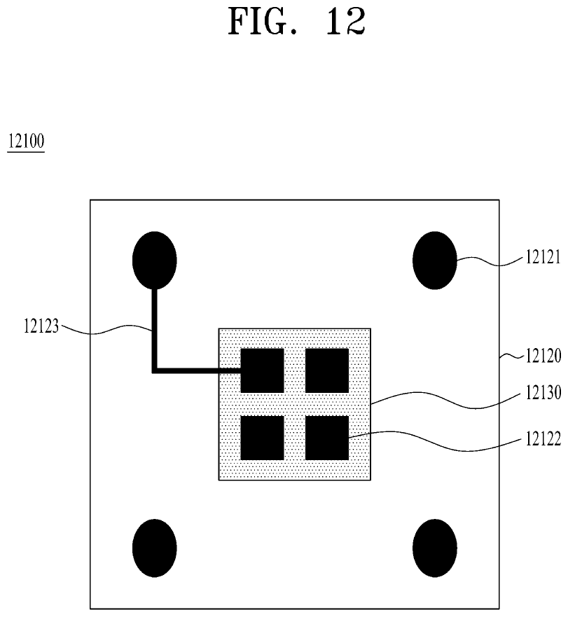

FIG. 12 is a schematic top view of a semiconductor light-emitting device package according to another embodiment.

As shown in FIG. 12, a light-emitting device package 12100 (e.g., the light-emitting device package described with reference to FIG. 11) according to this embodiment may include a driver 12120 (e.g., the driver described with reference to FIGS. 10 and 11) and a light-emitting device 12130 (e.g., the semiconductor light-emitting device described with reference to FIGS. 1 to 9 or the light-emitting device described with reference to FIGS. 10 and 11). According to this embodiment, the light-emitting device 12130 may be disposed on one surface of the driver 12120. In other words, the light-emitting device package 12100 according to this embodiment may include the driver 12120 and the light-emitting device 12130 that are arranged in a vertical direction. By vertically arranging the driver 12120 and the light-emitting device 12130, the light-emitting device package 12100 according to this embodiment may be implemented to have the same size as the size of the driver 12120 when viewed from above.

According to this embodiment, a first pad 12121 (e.g., the first pad described with reference to FIGS. 10 and 11), a second pad 12122 (e.g., the second pad described with reference to FIGS. 10 and 11), and an electrical wire 12123 (e.g., the electrical wire described with reference to FIGS. 10 and 11) may be disposed together on one surface of the driver 12120. By disposing the light-emitting device 12130 and the electrodes 12121, 12122, and 12123 together on the driver 12100, the light-emitting device package 12100 may be implemented even without a package substrate. In other words, the light-emitting device package 12100 according to this embodiment may be implemented without a separate wafer process. Accordingly, the light-emitting device package 12100 according to this embodiment may be implemented without a separate process for mounting the driver on a package substrate (e.g., the package substrate described with reference to FIG. 10), e.g., an IC flip process.

The driver 12120 according to this embodiment may have a rectangular cross-sectional shape. However, it is not limited thereto and may have any suitable shape and size depending on the application. For example, it may have a circular or triangular shape.

The first pad 12121 according to this embodiment may be disposed in a position to electrically connect the external circuitry and the driver 12120. For example, as shown in FIG. 12, one first pad may be disposed at each corner of the driver 12120. However, the positions and number of first pads 12121 are not limited thereto. Any positions and number of first pads 12121 may be used to serve as an electrical circuit to help drive the driver 12120. Similarly, while the first pad 12121 is illustrated in FIG. 12 as having a circular cross-sectional shape, it is not limited thereto. It may have any shape, such as a rectangle or other polygonal shape.

According to this embodiment, the second pad 12122 may be disposed in a position to electrically connect the driver 12120 and the light-emitting device 12130. For example, it may be disposed at the center of the driver 12120, as shown in FIG. 12, but is not limited thereto. While FIG. 12 illustrates four second pads 12122 per light-emitting device 12130, the number of second pads 12122 is not limited thereto. Any number of second pads 12122 may be used to electrically connect the driver 12120 and the light-emitting device 12130. Similarly, while the second pads 12122 according to this embodiment are illustrated as rectangular in FIG. 12, they may have any shape, such as a circular shape. While FIG. 12 shows that the second pads 12122, which are located on the bottom surface of the light-emitting device 12130, are visible when viewed from above, this is for illustrative purposes only and embodiments are not limited thereto.

At least one of the first pad 12121, the second pad 12122, or the electrical wire 12123 may be formed of metal including at least one of, for example, Cu, Ag, Al, Ni, Ti, Cr, Pd, Au, or Sn. However, it is not limited thereto. At least one of the first pad 12121, the second pad 12122, or the electrical wire 12123 may be any conductor. Furthermore, while only one electrical wire 12123 is shown in FIG. 12 for ease of illustration, embodiments are not limited thereto. Any number or shape of electrical wires may be used to electrically connect the first pad 12121 and the second pad 12122.

Although not shown in the figure, the light-emitting device package 12100 according to this embodiment may further include a protective member to protect the light-emitting device package 12100. The protective member may be disposed on the driver 12120 to cover the light-emitting device 12130. However, embodiments are not limited thereto, and the protective member may be disposed on at least one side surface of the driver 12120, or may be disposed to cover any surface including the light-emitting device 12130 and the driver 12120.

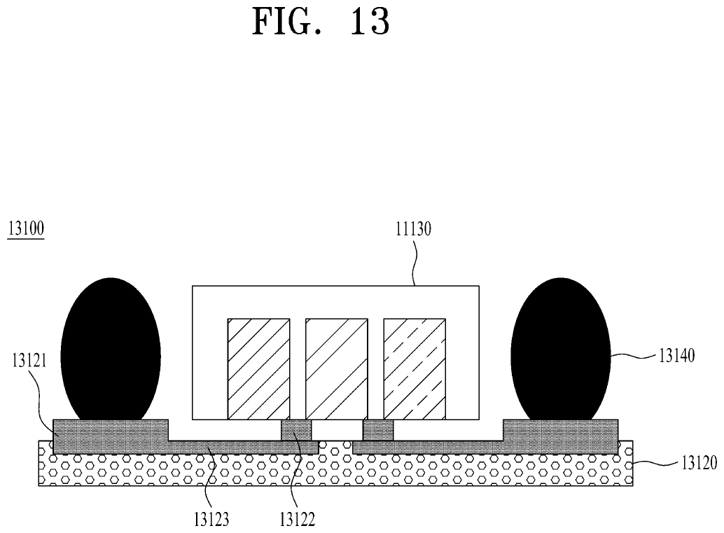

FIG. 13 is a schematic cross-sectional view of a semiconductor light-emitting device package according to another embodiment.

As shown in FIG. 13, a light-emitting device package 13100 (e.g., the light-emitting device package described with reference to FIGS. 11 and 12) according to this embodiment may include a driver 13120 (e.g., the driver described with reference to FIGS. 10 and 12), a light-emitting device 13130 (e.g., the semiconductor light-emitting device described with reference to FIGS. 1 to 9 or the light-emitting device described with reference to FIGS. 10 to 12), and a bonding portion 13140. The light-emitting device 13130 and the bonding portion 13140 according to this embodiment may be disposed on one surface of the driver 13120. That is, in the light-emitting device package 13100 according to this embodiment, the driver 13120 and the light-emitting device 13130 may be arranged in a vertical direction. Further, in the light-emitting device package 13100 according to this embodiment, the light-emitting device 13130 and the bonding portion 13140 may be arranged side by side. In addition, according to this embodiment, a first pad 13121 (e.g., the first pad described with reference to FIGS. 10 to 12), a second pad 13122 (e.g., the second pad described with reference to FIGS. 10 to 12), and an electrical wire 13123 (e.g., the electrical wire described with reference to FIGS. 10 to 12) may be disposed together on one surface of the driver 13120.

By disposing the light-emitting device 13130 and the bonding portion 13140 together on one surface of the driver 13120, the light-emitting device package 13100 according to this embodiment may be implemented even without a separate via for connecting the bonding portion 13140, the driver 13120, and the light-emitting device 13130 to each other. Thus, electrical connection between the bonding portion 13140, the driver 13120, and the light-emitting device 13130 may be realized without a separate process for forming the via, such as a through silicon via (TSV) process. Accordingly, the light-emitting device package 13100 according to this embodiment may include a more easily designable driver 13120. Furthermore, the light-emitting device package 13100 according to this embodiment may include the driver 13120 having a smaller area. That is, the light-emitting device package 13100 according to this embodiment may include an electrical wire 13123 printed on one surface of the driver 13120, a first pad 13121 and a second pad 13122 connected by the electrical wire 13123 and disposed on the electrical wire 13123, a bonding portion 13140 disposed on the first pad 13123, and a light-emitting device 13130 disposed on the second pad 13122.

The bonding portion 13140 according to this embodiment may more easily bond the external circuit and the driver 13120. The bonding portion 13140 according to this embodiment may be formed to have a height equal to the height of the light-emitting device 13130 or to be higher than the light-emitting device. The bonding portion 13140 according to this embodiment may employ, for example, but is not limited to, a solder bump or a copper bump. It may be formed of any material that is bondable and electrically conductive.

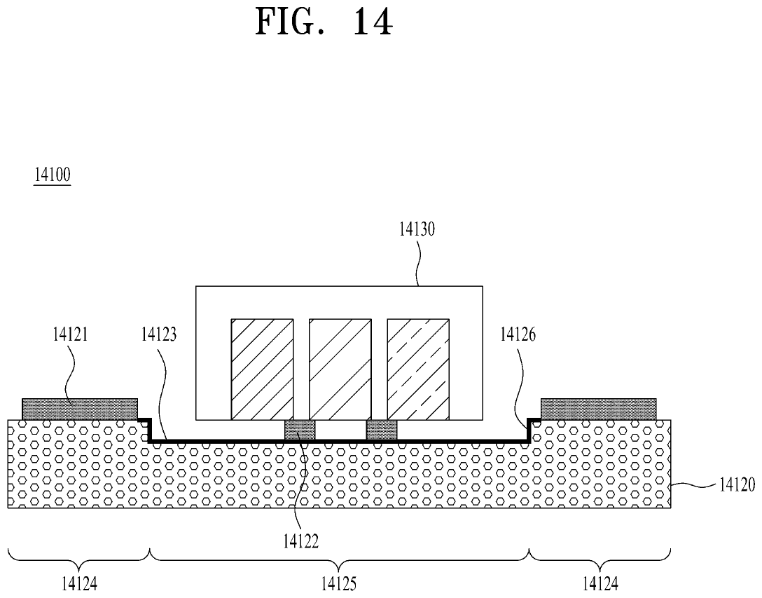

FIG. 14 is a schematic cross-sectional view of a semiconductor light-emitting device package according to another embodiment.

As shown in FIG. 14, a light-emitting device package 14100 (e.g., the light-emitting device package described with reference to FIGS. 11 to 13) according to this embodiment may include a driver 14120 (e.g., the driver described with reference to FIGS. 10 to 13) and a light-emitting device 14130 (e.g., the semiconductor light-emitting device described with reference to FIGS. 1 to 9 or the light-emitting device described with reference to FIGS. 10 to 13). Although not shown in FIG. 14, the light-emitting device package 14100 according to this embodiment may further include a bonding portion (e.g., the bonding portion described with reference to FIG. 13). In addition, a first pad 14121 (e.g., the first pad described with reference to FIGS. 10 to 13), a second pad 14122 (e.g., the second pad described with reference to FIGS. 10 to 13), and an electrical wire 14123 (e.g., the electrical wire described with reference to FIGS. 10 to 13) may be disposed together on one surface of the driver 14120 according to this embodiment. When the light-emitting device package 14100 further includes a bonding portion, the bonding portion may be disposed on the first pad 14121.

As shown in FIG. 14, the driver 14120 according to this embodiment may include a peripheral portion 14124 and a central portion 14125. The peripheral portion 14124 may have the shape of a single closed circuit formed along the edge of the driver 14120, and the central portion 14125 may be a portion located at the center of the driver 14120. In other words, the central portion 14125 may be shaped to be confined by the peripheral portion 14124. The first pad 14121 may be disposed on the peripheral portion 14124 of the driver 14120, and the second pad 14123 may be disposed on the central portion 14125 of the driver 14120. When viewed from above, the cross-section of the center portion 14125 according to this embodiment may be circular or polygonal, but is not limited thereto.

According to this embodiment, the peripheral portion 14124 and the central portion 14125 of the driver 14120 may be formed to have a step therebetween. Specifically, as shown in FIG. 14, the peripheral portion 14124 may be formed at a higher level than the central portion 14125. As the peripheral portion 14124 and the central portion 14125 are formed to have a step therebetween, the driver 14120 according to this embodiment may allow light emitted from the light-emitting device 14130 to be guided in a desired direction. For example, when the light-emitting device package 14100 and a circuit board are electrically connected according to this embodiment, light emitted from the light-emitting device 14130 may be guided to the circuit board without leakage. The step 14126 between the peripheral portion 14124 and the central portion 14125 may be formed perpendicular to the driver 14120, but is not limited thereto. It may be formed to have a slope with respect to the driver 14120. The height of the step 14126 according to this embodiment is formed to be less than the height of the side surface of the light-emitting device 14130 in FIG. 14, but is not limited thereto. It may be formed to be equal to the height of the side surface of the light-emitting device 14130, or may be formed to be greater than the height of the side surface.

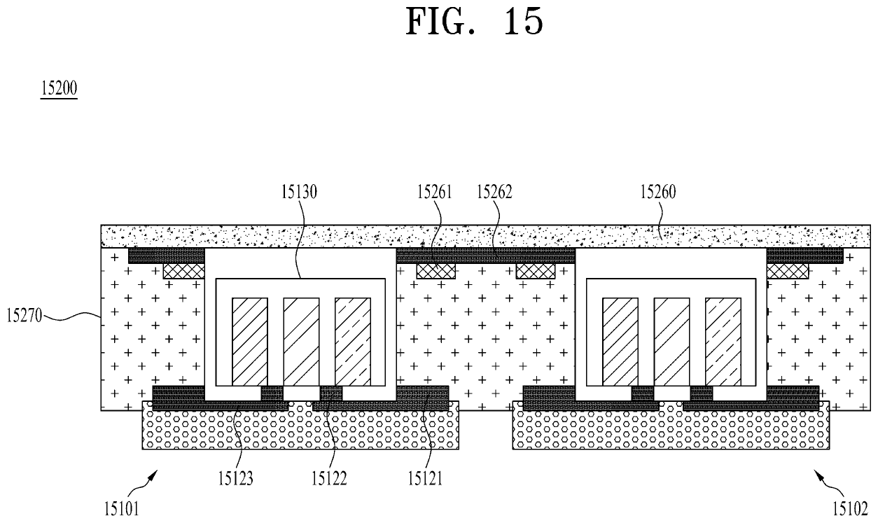

FIG. 15 is a schematic cross-sectional view of a display device according to another embodiment.

A display device 15200 according to this embodiment may include a circuit board 15260 (e.g., the circuit board described with reference to FIG. 14) and one or more light-emitting device packages 15101 and 15102 (e.g., the light-emitting device package described with reference to FIGS. 11 to 14). The light-emitting device packages 15101 and 15102 according to this embodiment may be formed on one surface of the circuit board 15260. While two light-emitting device packages 15101 and 15102 are shown in FIG. 15, the number of light-emitting device packages 15101 and 15102 is not limited thereto.

Each of the light-emitting device packages 15100 according to this embodiment may include a driver 15120 (e.g., the driver described with reference to FIGS. 10 to 14) and a light-emitting device 15130 (e.g., the semiconductor light-emitting device described with reference to FIGS. 1 to 9 or the light-emitting device described with reference to FIGS. 10 to 14). The light-emitting device 15130 according to this embodiment may be disposed on one surface of the driver 15120. In other words, in the light-emitting device package 15100 according to this embodiment, the driver 15120 and the light-emitting device 15130 may be arranged in a vertical direction. In other words, in the light-emitting device package 15100 according to this embodiment, the driver 15120 and the light-emitting device 15130 may be integrated with each other. Accordingly, each of the light-emitting device packages 15101 and 15102 are repairable, which is advantageous in terms of maintenance. As the driver 15120 and the light-emitting device 15130 are arranged in a vertical direction, the light-emitting device package 15101, 15102 may be implemented to have the same size as the size of the driver 15120 when viewed from above, according to the present embodiment. In this way, by forming the size of the light-emitting device packages 15101 and 15102 to be the same or similar to the size of the driver 15120, a display module having an ultra-fine pitch may be implemented. In other words, the display device 15200 according to this embodiment may reduce the size of one pixel by disposing the light-emitting device 15130 (e.g., a semiconductor light-emitting device emitting R, G, and B) on the driver 15120.

Specifically, a first pad 15121 (e.g., the first pad described with reference to FIGS. 10 to 14) and a second pad 15122 (e.g., the second pad described with reference to FIGS. 10 to 14) may be disposed on one surface of the driver 15120. According to this embodiment, the first pad 15121 may be an electrode that electrically connects the circuit board 15260 and the driver 15120 to each other. The second pad 15122 may be an electrode that electrically connects the driver 15120 and the light-emitting device 15130. According to this embodiment, the first pad 15121 and the second pad 15122 may be electrically connected to each other by an electrical wire 15123 (e.g., the electrical wire described with reference to FIGS. 10 to 14) formed on one surface of the driver 15120. Thus, the first pad 15121, the second pad 15122, and the electrical wire 15123 may be located together on one surface of the driver 15120. In other words, nothing may be formed on the opposite surface of the driver 15120 where the first pad 15121, the second pad 15122, and the electrical wire 15123 are not positioned.

The display device 15200 according to this embodiment may further include a transparent electrode portion 15270 for electrical connection of the circuit board 15260 and the light-emitting device packages 15101 and 15102. The transparent electrode portion 15270 may be a metal mesh 15270, and may include, for example, a Cu mesh.

The circuit board 15260 according to this embodiment may include electrode pads 15261 disposed on one surface of the circuit board 15260 facing the light-emitting device packages 15101 and 15102, and an electrical wire 15262 electrically connected between the electrode pads 15261 or between the electrode pads 15261 and the circuit board 15260. In this case, the electrode pads 15261 may be formed at positions facing the first pad 15121 included in the light-emitting device package 15101. According to embodiments, at least one of the electrode pad 15261 and the electrical wire 15262 may be formed of metal including, for example, at least one of Cu, Ag, Al, Ni, Ti, Cr, Pd, Au, or Sn, but is not limited thereto.

The circuit board 15260 according to this embodiment may be, for example, a printed circuit board (PCB). The circuit board 15260 according to this embodiment may be, for example, a transparent circuit board that allows light emitted from the light-emitting device 15130 to be transmitted therethrough. Accordingly, light emitted from the light-emitting device 15130 may be transmitted through the circuit board 15260 and emitted to the outside from the display device 15200. Alternatively, the circuit board 15260 may be an opaque circuit board that includes, for example, a plurality of vias. In this case, light emitted from the light-emitting device 15130 may be emitted to the outside from the display device 15200 through the vias included in the circuit board 15260.

As the display device 15200 includes the light-emitting device packages 15101 and 15102, each of which includes the driver 15120, the display device 15200 according to this embodiment may be implemented without any additional components for driving. Thus, the circuit board 15260 may be a single-sided circuit board with electrical circuits printed on only one surface. Accordingly, the display device 15200 according to this embodiment may reduce the cost of the circuit board. Furthermore, with the display device 15200, a small curvature and transparent display may be implemented.

The display device 15200 according to the embodiment may emit light from the light-emitting device 15130 toward a person who sees the display device, that is, toward the circuit board. In this case, the display device 15200 may have a structure in which the light-emitting device packages 15101 and 15102 are protected by a transparent film (not shown). Therefore, the light-emitting device packages 15101 and 15102 are less likely to fall off the display device 15200.

Although not shown in the figure, the driver 15120 according to this embodiment may further include (e.g., the peripheral portion described with reference to FIG. 14) and a center portion (e.g., the center portion described with reference to FIG. 14). The peripheral portion may have the shape of a single closed circuit formed along the edge of the driver 15120 according to embodiments, and the central portion may be a portion located at the center of the driver 15120. In other words, the central portion may be shaped to be confined by the peripheral portion. The first pad 15121 may be disposed on the peripheral portion of the driver 15120, and the second pad 15123 may be disposed on the central portion of the driver 15120. When viewed from above, the cross-section of the center portion according to this embodiment may be circular or polygonal, but is not limited thereto.

According to this embodiment, the peripheral portion and the central portion of the driver 15120 may be formed to have a step therebetween. Specifically, the peripheral portion may be formed at a higher level than the central portion. As the peripheral portion and the central portion are formed to have a step therebetween, the driver 15120 according to this embodiment may allow light emitted from the light-emitting device 15130 to be guided in a desired direction. For example, when the light-emitting device package 15100 and the circuit board 15260 are electrically connected according to this embodiment, light emitted from the light-emitting device 15130 may be guided to the circuit board without leakage. The step between the peripheral portion and the central portion may be formed perpendicular to the driver 15120, but is not limited thereto. It may be formed to have a slope with respect to the driver 15120. The height of the step according to this embodiment may be formed to be less than the height of the side surface of the light-emitting device 15130, or may be formed to be equal to the height of the side surface of the light-emitting device 15130 or to be greater than the height of the side surface.

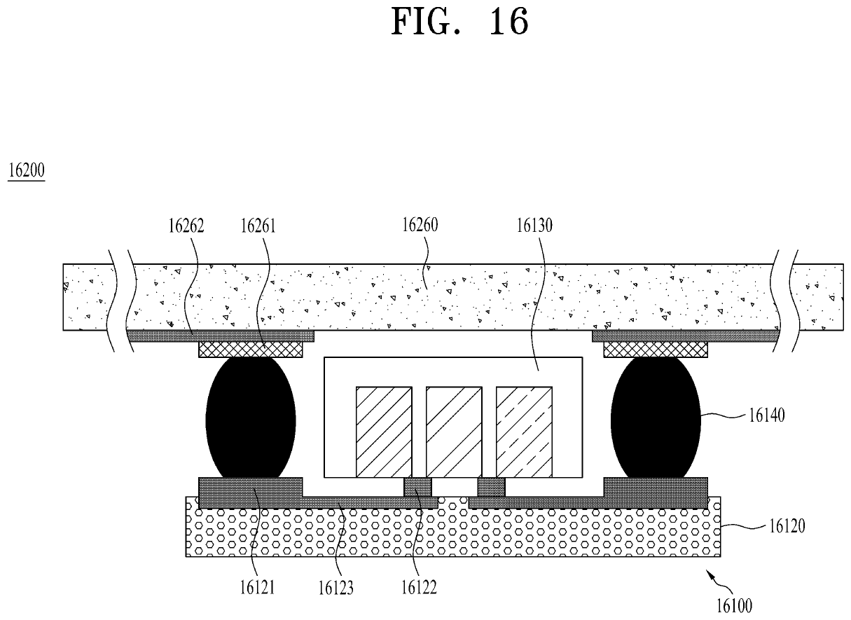

FIG. 16 is a schematic cross-sectional view of a display device according to another embodiment.

A display device 16200 according to this embodiment may include a circuit board 16260 (e.g., the circuit board described with reference to FIGS. 14 and 15) and one or more light-emitting device packages 16100 (e.g., the light-emitting device package described with reference to FIGS. 11 to 15). The light-emitting device packages 16100 according to this embodiment may be formed on one surface of the circuit board 16260.

The light-emitting device package 16100 according to this embodiment may include a driver 16120 (e.g., the driver described with reference to FIGS. 10 to 15), a light-emitting device 16130 (e.g., the semiconductor light-emitting device described with reference to FIGS. 1 to 9 or the light-emitting device described with reference to FIGS. 10 to 15), and a bonding portion 16140 (e.g., the bonding portion described with reference to FIGS. 13 and 14). The light-emitting device 16130 and the bonding portion 16140 according to this embodiment may be disposed on one surface of the driver 16120. In other words, in the light-emitting device package 16100 according to this embodiment, the driver 16120 and the light-emitting device 16130 may be arranged in a vertical direction. Further, in the light-emitting device package 16100 according to this embodiment, the light-emitting device 16130 and a bonding portion 16140 may be arranged side by side. Further, a first pad 16121 (e.g., the first pad described in FIGS. 10 to 15), a second pad 16122 (e.g., the second pad described with reference to FIGS. 10 to 15), and an electrical wire 16123 (e.g., the electrical wire described with reference to FIGS. 10 to 15) may be disposed together on one surface of the driver 16120.

The circuit board 16260 according to this embodiment (e.g., the circuit board described with reference to FIG. 15) may include electrode pads 16261 disposed on one surface of the circuit board 16260 facing the light-emitting device package 16100, and electrical wires 16262 electrically connected between the electrode pads 16261 or between the electrode pads 16261 and the circuit board 16260. In this case, the electrode pads 16261 may be formed at positions facing the first pads 16121 included in the light-emitting device package 16101.

According to this embodiment, the bonding portion 16140, disposed on the first pad 16121, may be formed to be higher than the light-emitting device 16130. The bonding portion 16140 may bond the circuit board 16260 and the light-emitting device package 16100 by partially melting during the process of bonding the circuit board 16260 and the light-emitting device package 16100. Specifically, the bonding portion 16140 may connect between the first pad 16121 on the driver 16120 and the electrode pad 16261 on the circuit board 16260 to bond and connect the driver 16120 and the circuit board 16260. The bonding portion 16140 according to this embodiment may employ, for example, but is not limited to, a solder bump or a copper bump. It may be formed of any material that is bondable and electrically conductive.

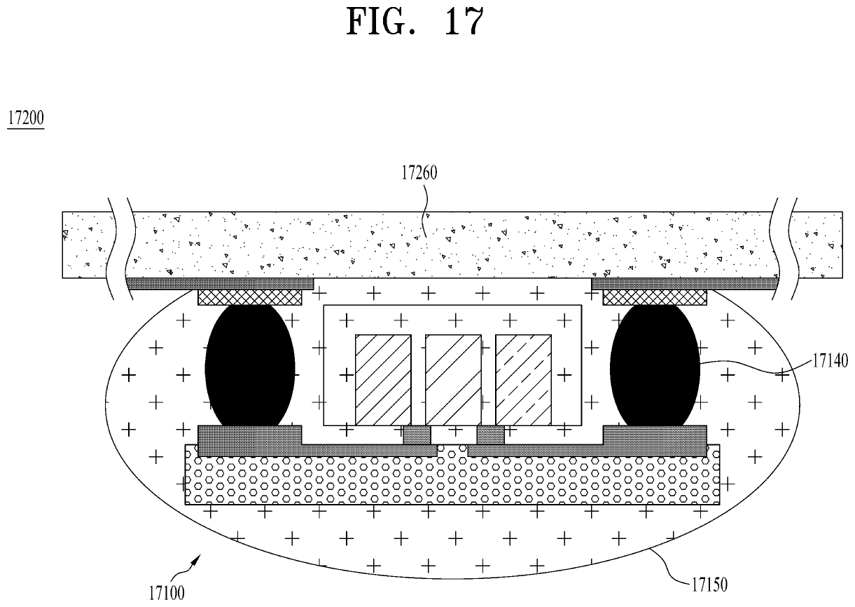

FIG. 17 is a schematic cross-sectional view of a display device according to another embodiment.

The display device 17200 according to this embodiment may include a circuit board 17260 (e.g., the circuit board described with reference to FIGS. 14 to 16) and one or more light-emitting device packages 17100 (e.g., the light-emitting device packages described with reference to FIGS. 11 to 16). The light-emitting device package 17100 according to this embodiment may include a bonding portion 17140 (e.g., the bonding portion described with reference to FIGS. 13, 14, and 16).

The light-emitting device package 17100 may further include a protective member 17150 to protect the light-emitting device package 17100. The protective member 17150 may be disposed to partially or fully cover the light-emitting device package 17130 to protect components included in the display device 17200.

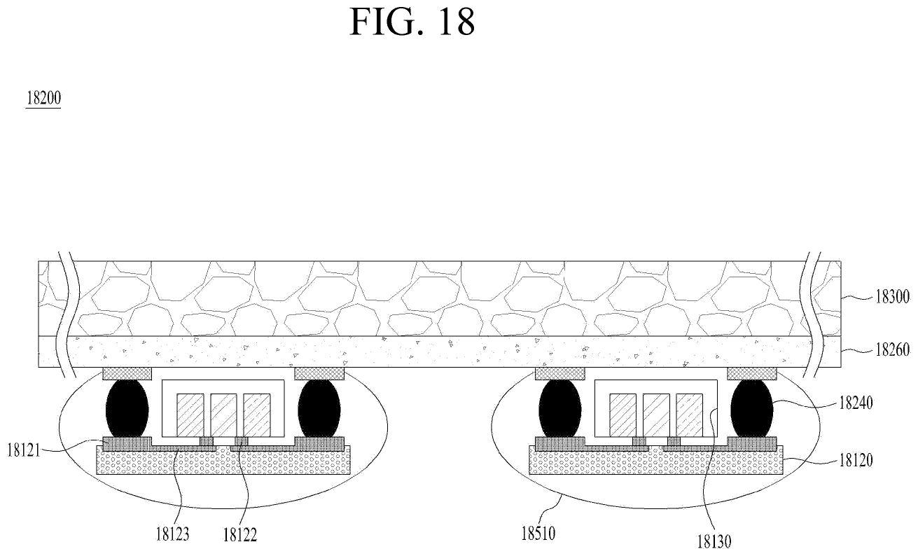

FIG. 18 is a schematic cross-sectional view of a display device according to another embodiment.

A display device 18200 according to this embodiment includes a circuit board 18260 (e.g., the circuit board described with reference to FIGS. 14 to 17), a bonding portion 18140 (e.g., the bonding portion described with reference to FIGS. 13, 14, 16, and 17), a driver 18120 (e.g., the driver described with reference to FIGS. 10 to 16), a light-emitting device 18130 (e.g., the semiconductor light-emitting device described with reference to FIGS. 1 to 9 or the light-emitting device described with reference to FIGS. 10 to 16), and a glass substrate 18300.

The display device 18200 may further include a protective member 18150 (e.g., the protective member described with reference to FIG. 17). The protective member 18150 protects at least a portion of the circuit board 18260, the bonding portion 18140, the driver 18120, and the light-emitting device 18130.

The circuit board 18260 is a substrate on which electrical circuits are formed, and includes, for example, a PCB on which circuits are printed. The circuit board 18260 includes a transparent circuit board. The electrical circuit is, for example, the electrode pads described with reference to FIG. 15 and/or FIG. 16. Thus, the circuit board 18260 is electrically connected to a target connected to an electrode pad through the electrode pad formed on one surface of the circuit board 18260.

The bonding portion 18140 is connected to the electrode pad to electrically connect the circuit board 18260 and the driver 18120. The bonding portion 18140 may be any electrical conductor, for example.

The driver 18120 is electrically connected to the circuit board 18260 through the bonding portion 18140. The driver 18120 includes a first pad 18121 (e.g., the first pad described with reference to FIGS. 10 to 16) and a second pad 18122 (e.g., the second pad described with reference to FIGS. 10 to 16) on one surface. That is, the first pad 18121 and the second pad 18122 are formed on the same surface of the driver 18120.

The first pad 18121 is connected to the bonding portion 18140 through one side thereof that is not in contact with the driver 18120. That is, the driver 18120 is electrically connected to the bonding portion 18140 through the first pad 18121.

The second pad 18122 is connected to the light-emitting device 18130 through one side thereof that is not in contact with the driver 18120. That is, the driver 18120 is electrically connected to the light-emitting device 18130 through the second pad 18122.

The first pad 18121 and the second pad 18122 are electrically connected by an electrical wire 18123. FIG. 18 is only a simplified view for illustrative purposes, and the display device 18200 may include electrical circuitry and electrode pads not shown in FIG. 18.

The light-emitting device 18130 is formed on the second pad 18122 and emits light toward the circuit board 18260.

With this structure, the light-emitting device 18130 is provided as a component integrated with the driver 18120. That is, due to the integration of the light-emitting device 18130 and the driver 18120, the display device 18200 does not require a separate process, package board, via, or the like for electrically connecting the light-emitting device 18130 and the driver 18120.

Furthermore, when a plurality of integrated light-emitting devices 18130 and drivers 18120 connected to the circuit board 18260 is provided, such integration of the light-emitting device 18130 and the driver 18120 allows any integration of the light-emitting device 18130 and the driver 18120 undergoing a problem to be repaired alone. Thus, the display device 18200 is easy to maintain.

The glass substrate 18300 is formed on the other surface of the circuit board 18260. The glass substrate 18300 is formed in contact with the circuit board 18260 without the need for a transparent film.

Accordingly, the display device 18200 according to embodiments does not require a separate material or process for bonding the glass substrate 18300 to the driver 18120 including the light-emitting device 18130. For example, the display device 18200 does not require a separate filling material or sealing material, such as a transparent film, for bonding the driver 18120 and the glass substrate 18300. With this structure, the display device 18200 provides ease of assembly.

The above description is merely illustrative of the technical idea of the present disclosure. Those of ordinary skill in the art to which the present disclosure pertains will be able to make various modifications and variations without departing from the essential characteristics of the present disclosure.

Therefore, embodiments disclosed in the present disclosure are not intended to limit the technical idea of the present disclosure, but to describe, and the scope of the technical idea of the present disclosure is not limited by such embodiments.

The scope of protection of the present disclosure should be interpreted by the claims below, and all technical ideas within the scope equivalent thereto should be construed as being included in the scope of the present disclosure.

1. A light-emitting device package comprising:
a light-emitting device; and
a driving part configured to control driving of the light-emitting device, the driving part comprising:
a first pad; and
a second pad electrically connected to the light-emitting device,
wherein the first pad and the second pad are disposed on one surface of the driver,
wherein the light-emitting device is disposed on the second pad.

2. The light-emitting device package of claim 1, further comprising:
a bonding portion disposed on the first pad and electrically connected to the driver.

3. The light-emitting device package of claim 2, wherein, in a direction facing the driver, a height of the bonding portion is equal to or greater than a height of the light-emitting device.

4. The light-emitting device package of claim 1, wherein, when viewed from above, a cross-sectional area of the light-emitting device package is equal to a cross-sectional area of the driver.

5. The light-emitting device package of claim 1, further comprising:
a protective member disposed on the driver to cover the light-emitting device.

6. The light-emitting device package of claim 1, wherein the driver comprises a peripheral portion and a central portion,
wherein the first pad is disposed on the peripheral portion,
wherein the second pad is disposed on the central portion,
wherein the peripheral portion and the central portion are arranged to have a step therebetween.

7. A display device comprising:
a circuit board comprising an electrode pad; and
one or more light-emitting device packages disposed on one surface of the circuit board, and electrically connected to the circuit board,
wherein each of the one or more light-emitting device packages comprises:
a light-emitting device; and
a driver configured to control driving of the light-emitting device, the driver comprising:
a first pad electrically connected to the electrode pad; and
a second pad electrically connected to the light-emitting device,
wherein the first pad and the second pad are disposed on one surface of the driver.

8. The display device of claim 7, further comprising:
a bonding portion disposed on the first pad to electrically connect the circuit board and the driver.

9. The display device of claim 7, wherein the circuit board is a transparent circuit board allowing light from the light-emitting device to be transmitted therethrough.

10. The display device of claim 7, wherein the circuit board is an opaque circuit board comprising a passage allowing light from the light-emitting device to pass therethrough.

11. The display device of claim 7, wherein the circuit board comprises metallic wiring formed on only one surface thereof facing the light-emitting device package.

12. The display device of claim 7, wherein, when viewed from above, each of the one or more light-emitting device packages has an identical cross-sectional area as the driver.

13. The display device of claim 7, further comprising:
a protective member disposed on the driver to cover the light-emitting device packages.

14. The display device of claim 7, further comprising:
a glass substrate arranged to face away from the one or more light-emitting device packages, the glass substrate being formed on an opposite surface of the circuit board.

15. A display device comprising:
a circuit board comprising an electrode pad;
a driver arranged to face one surface of the circuit board and spaced apart from the circuit board by a specific distance, the driver comprising: a first pad for connection with the circuit board; and a second pad for connection of the light-emitting device;
a light-emitting device bonded to the second pad of the driver by an electrode portion; and
a bonding portion connected to the first pad of the driver and the electrode pad of the circuit board.

16. The display device of claim 15,
wherein the circuit board is a transparent circuit board allowing light from the light-emitting device to be transmitted therethrough

17. The display device of claim 15, wherein the circuit board is an opaque circuit board comprising a passage allowing light from the light-emitting device to pass therethrough.

18. The display device of claim 15, wherein the circuit board comprises metallic wiring formed on only one surface thereof facing the light-emitting device.

19. The display device of claim 15, further comprising:
a protective member disposed to cover the light-emitting device and the driver.

20. The display device of claim 15, further comprising:
a glass substrate arranged to face away from the driver, and formed in contact with an opposite surface of the circuit board.

21-22. (canceled)
